(19) United States
(12) Patent Application Publication
(10) Pub. No.: US 2005/0024074 A1
(43) Pub. Date: Feb. 3, 2005

(54) Method and apparatus for characterizing an electronic circuit

(76) Inventors: Gary Benjamin, Fort Collins, CO (US); Glen Colon-Bonet, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/633,386

(22) Filed: Aug. 1, 2003

(51) Int. Cl. G01R 31/02

(52) U.S. Cl. 324/763

(57) ABSTRACT

Design information representing an electrical circuit is received and an electrical circuit condition requiring test is identified. A design verification test is determined, and evaluated for effectiveness in exercising the identified electrical circuit condition. Electrical circuit conditions include faults such as speed paths, races, coupling events, noise events, and voltage and temperature sensitivities.

### BACKGROUND

Much of the digital revolution that has occurred during the past decade has occurred in the area of Very Large Scale Integration (VLSI) chip design. While the cost to the end consumer of the advances in chip technology has dropped by orders of magnitude during this period, much of the cost reduction has come about because of the ability of chip designers and manufacturers to incorporate more and more functionality into a single chip. As a result, some chip designs now comprise hundreds of millions of transistors.

These advances in chip technology would not have been possible without concomitant advances in the computers and software that implement the tools that are used to design, test, and verify today's VLSI chips. Chip design employs the use of very sophisticated simulation tools that typically result in a design with characteristics that are well understood within practical limits of chip gate count and computer run time. Although these practical limits continue to expand as technology improves, the densities of chips are increasing at an even faster rate. Therefore, unavoidable uncertainties in the performance of chips remain when the chip design process enters the fabrication phase. These uncertainties must be resolved in the post-fabrication phase.

Generally, a chip is designed to meet requirements specified before the design process begins. During the design process, implementations of the chip are proposed and tested against the design specifications. The design process also predicts performance expected of the fabricated chip. Tools used by chip designers are able to reliably and accurately predict actual chip performance, assuming that the fabrication process is ideal. To a degree, these tools also can account for non-ideal aspects of chip fabrication. Inevitably, however, post-fabrication behavior of chips deviates from the behavior predicted during the design phase—a result of imperfections in the fabrication process that are difficult to predict in advance.

The primary defense against post-fabrication design deficiencies is testing. Once a chip has been fabricated, the testing process involves comparing actual chip performance and functionality with that of the original design specification and with the performance and functionality predicted during the pre-fabrication design process. One aspect of post-fabrication testing involves attempting to discover “stuck-at” faults. According to this aspect of testing, a certain test point internal to the chip may, because of errors during the fabrication process, be “stuck” in either a high or low state, thereby defining a fault condition that may be discovered by means of testing.

A stuck-at fault may be discovered by determining a first test condition that produces a first known output when no fault is present and that produces a second known output when a certain test point is stuck in a low state. A second test condition may produce a third known output when no fault is present and a fourth known output when the test point is stuck in a high state. By exercising the first and second test conditions, the test process may discover whether the test point is stuck in either the high or low state, thereby discovering whether a stuck-at fault exists with respect to the identified test point. Although not all stuck-at faults can be discovered in this manner, the discovery of stuck-at faults has been of sufficient interest to chip manufacturers that many methods and products have been spawned in the prior art to address the issue of stuck-at faults.

Stuck-at faults represent only a fraction of the circuit conditions that can influence chip performance and functionality. Other types of circuit events also can influence the performance and functionality of practical chips. However, while prior art has focused on faults caused by stuck-at conditions, faults corresponding to more general kinds of faulty electrical conditions are not considered in currently available pre-fabrication and post-fabrication testing products.

### SUMMARY

One exemplary method teaches that a design verification test is determined for testing an electrical circuit condition identified in a circuit design. The effectiveness of the design verification test in exercising the electrical circuit condition is evaluated. In the event that the determined design verification test is found to be ineffective, a second design verification test is determined. The effectiveness of the second determined design verification test is then evaluated.

### BRIEF DESCRIPTION OF THE DRAWINGS

Several alternative embodiments will hereinafter be described in conjunction with the appended drawings and figures, wherein like numerals denote like elements, and in which:

FIG. 1 is a flow diagram of a representative embodiment of a method for characterizing an electronic circuit;

FIG. 2 is a flow diagram of a representative embodiment of a method for evaluating the effectiveness of a design verification test;

FIG. 3 is a schematic diagram of one electrical circuit use case that illustrates an electrical circuit condition requiring test;

FIG. 4 is a flow diagram of a representative embodiment of a method for determining a design verification test;

FIG. 5 is a flow diagram of a representative embodiment of a method for evaluating the effectiveness of a design verification test;

FIG. 6 is a flow diagram of an alternative embodiment of a method for evaluating the effectiveness of a design verification test;

FIG. 7 is a flow diagram of a representative embodiment of a method of receiving design information;

FIG. 8 is a flow diagram of a representative embodiment of a method for identifying an electrical circuit condition;

FIG. 9 is a schematic diagram of one representative electrical circuit use case that illustrates another electrical circuit condition requiring test;

FIG. 10 is a schematic diagram of yet another representative electrical circuit use case that illustrates an electrical circuit condition requiring test;

FIG. 11 is a flow diagram of an alternative representative embodiment of a method for identifying an electrical circuit condition that requires test;

FIG. 12 is a flow diagram of a representative embodiment of a method for evaluating the effectiveness of a design verification test;

FIG. 13 is a flow diagram of a representative embodiment of a method for verifying the design of an electronic circuit based upon an electrical circuit condition;

FIG. 14 is a flow diagram of a representative embodiment of one alternative method for verifying the design of an electronic circuit based upon an electrical circuit condition;

FIG. 15 is a block diagram of a representative embodiment of a computing platform that is capable of characterizing an electronic circuit;

FIG. 16 is a data flow diagram of a representative embodiment of a device that is capable of characterizing an electronic circuit;

FIG. 17 is a data flow diagram that illustrates the operation of a representative embodiment of a design verification test selector;

FIG. 18 is a data flow diagram that illustrates the operation of a representative embodiment of an evaluation unit;

FIG. 19 is a data flow diagram that illustrates the operation of an alternative representative embodiment of an evaluation unit;

FIG. 20 is a data flow diagram that illustrates the operation of a representative embodiment of a design information receiver;

FIG. 21 is a data flow diagram that illustrates the operation of a representative embodiment of a circuit condition identifier;

FIG. 22 is a data flow diagram that illustrates the operation of an alternative representative embodiment of a circuit condition identifier;

FIG. 23 is a data flow diagram that illustrates the operation of another alternative representative embodiment of an evaluation unit; and

FIG. 24 is a data flow diagram that illustrates the operation of an alternative representative embodiment of a device that is capable of characterizing an electronic circuit.

### DETAILED DESCRIPTION

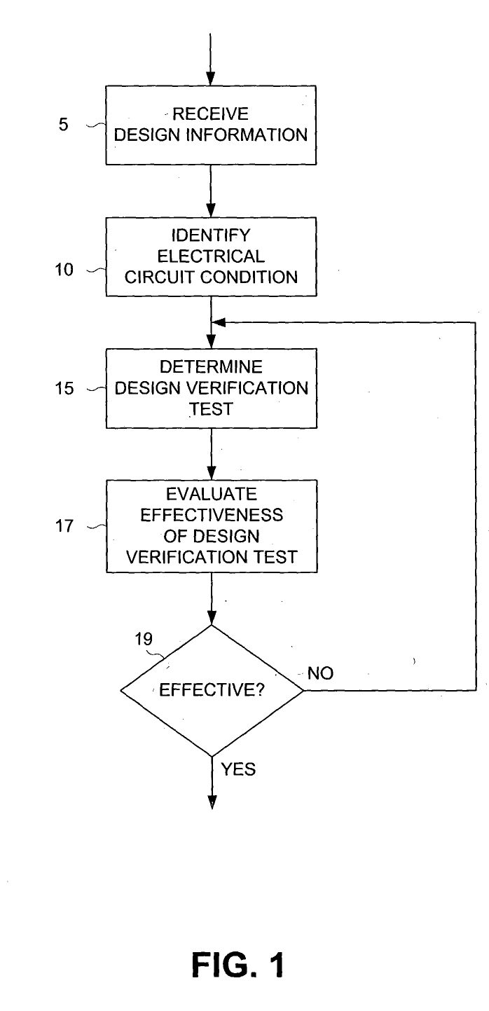

FIG. 1 is a flow diagram of a representative embodiment of a method for characterizing an electronic circuit. According to this variation of the method, design information is received from a circuit design tool (step 5). According to one illustrative variation of this method, design information is received in the form of circuit nodes and voltages on those nodes at successive time instants. By inspecting the design information, an electrical circuit condition that requires test is identified (step 10). Electrical conditions that require test are those conditions that can lead to a significant risk of chip malfunction during operation of the chip. Such a condition is here termed a “soft” fault in contrast to the “hard” faults represented by the “stuck-at” faults evaluated by prior art evaluation methods. Examples of these soft faults include speed paths, races, coupling events, noise events, and voltage and temperature sensitivities. In another example variation of the method, a circuit designer identifies a part of a design believed to be particularly sensitive to a soft fault. According to one variation of the present method, that part of the circuit design comprises a particular list of nodes requiring test. These nodes are then defined to exhibit soft faults. These techniques for identifying soft faults are provided in order to illustrate the present method, not to limit the scope of the claims appended hereto.

One example of a soft fault is a soft speed path fault that can arise when a logic signal at the output of a first latch is coupled through intervening logic to the input of a second latch. When the time delay in the intervening logic approaches a clock period, then a soft speed path fault is identified. The clock period is typically the inverse of the frequency of the clock signal used to operate a circuit. Another example of a soft fault comprises a soft race fault that arises when the clock signal at the input of a first latch is skewed with respect to the clock signal at the input to a second latch. In this case, a signal can arrive at a latch during the wrong cycle of a clock, thereby causing the chip to malfunction. A soft coupling event fault occurs when the level of one signal voltage (a victim) in a circuit is influenced by a transition in the level of another signal voltage (an aggressor) in the circuit. In another example, a victim signal may be influenced by particular transitions (LOW-to-HIGH or HIGH-to-LOW) in the levels of more than one aggressor signal. These examples of electrical circuit conditions that require test are introduced only to illustrate the applicability of the present method and are not intended to limit the scope of the appended claims.

Once an electrical circuit condition requiring test has been identified, a first design verification test is determined (step 15), and its effectiveness in exercising the circuit condition also is determined (step 17). In the event that the design verification test is not effective in exercising the electrical circuit condition (step 19), a second design verification test is determined and likewise evaluated.

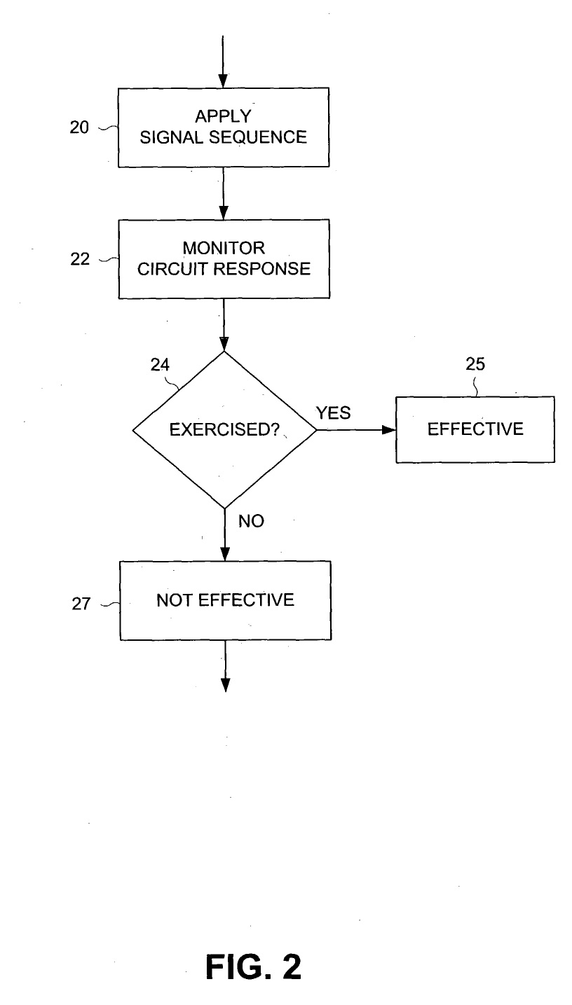

FIG. 2 is a flow diagram of a representative embodiment of a method for evaluating the effectiveness of a design verification test. According to one example variation of this method, a design verification test comprises a particular set of sequences of signal levels applied to an electrical circuit (step 20), and the behavior of the electrical circuit is evaluated (step 22). By monitoring the behavior of the electrical circuit, this example method determines if the electrical condition is exercised (step 24). In the event that the electrical condition is exercised, the design verification test is declared to be effective (step 25). Otherwise, it is declared to be ineffective (step 27).

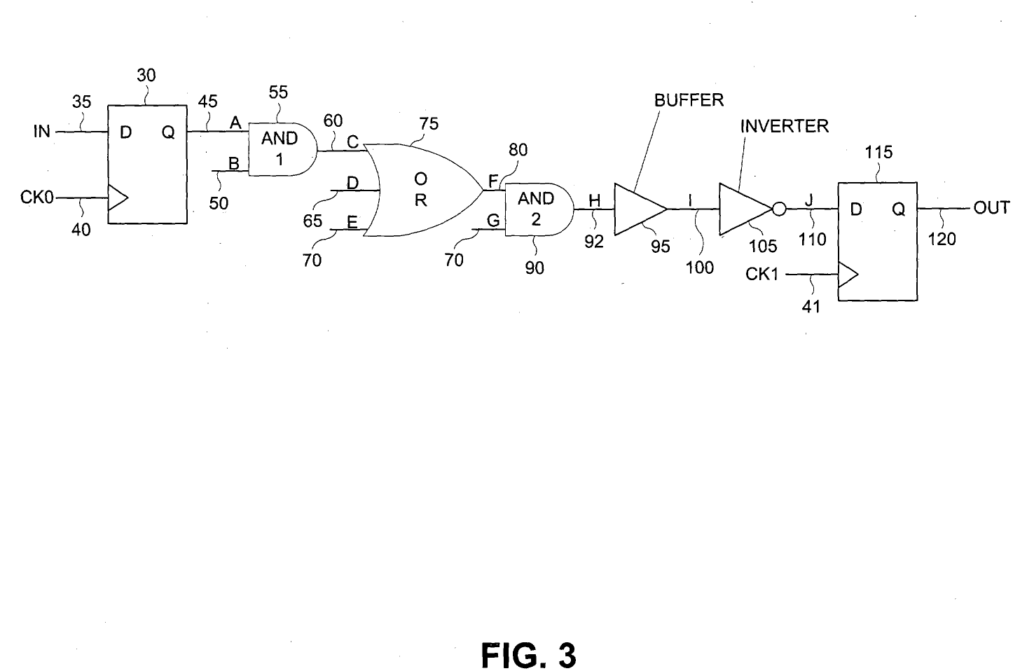

FIG. 3 is a schematic diagram of one electrical circuit use case that illustrates an electrical circuit condition requiring test. (In the discussion of the example use cases presented herein, a HIGH state corresponds to a logic 1; a LOW state corresponds to a logic 0.) The circuit of FIG. 3 represents the type of design information that is typically produced by a circuit design tool. Referring to this illustrative use case, the circuit comprises two latches: a first latch 30 and a second latch 115 with several intervening logic gates, each characterized, in part, by an associated delay. The first latch 30 is clocked by a clock signal CK0 40; the second latch 30 is clocked by a clock signal CK1 41. In one particular use case, CK0 40 and CK1 41 are identical clock signals with no skew between them. In broad terms, speed path analysis of this circuit examines whether the effect of an input clocked into the first latch 30 on the leading edge of clock cycle N propagates properly to the input of the second latch 115 and stabilizes before leading edge of clock cycle N+1.

In more detail, the circuit shown in the figure comprises a first D flip-flop or latch 30, having an input signal IN 35 applied to its D input. A clock signal CK0 40 is applied to the clock input of the first latch 30. The output of the latch 30 is connected to a first input A 45 of a first AND gate 55; signal B 50 is applied to a second input of said first AND gate 55. The output of the first AND gate 55 connects to a first input C 60 of an OR gate 75. Signals D 65 and E 70 are applied to respective second and third inputs to the OR gate 75. The output of the OR gate 75 connects to a first input F 80 of a second AND gate 90. Signal G 85 is applied to a second input of said second AND gate 90. The output of the second AND gate 90 connects to the input of a buffer 95, and the buffer output connects to the input 1100 of an inverter 105. The output J 110 of the inverter 105 connects to the D input of a second latch 115, the output of which is the signal OUT 120. Clock signal CK1 41 is applied to the clock input of the second latch 115.

According to this use case, which is not intended to limit the scope of the appended claims, the input signal IN 35 is held in a HIGH state, and the clock signal CK0 40 is applied to the first latch 30. In this use case, the effect of applying the clock CK0 40 is observed at various points A 45, C 60, F 80, H 92, I 100, and J 110 of the circuit only after some delay. A static timing analysis tool is used to estimate these delays. In one illustrative use case, the static timing analysis tool calculates the time delay between the transition of the input and the transition of the output of each element in the A-C-F-H-I-J (45, 60, 80, 92, 100, 110) chain.

In one particular example, a signal propagating through the delay of the path defined by the signals A-C-F-H-I-J (45, 60, 80, 92, 100, 110) represents a marginal condition that should be tested. According to this illustrative use case, one way of calculating this delay is to hold the input signal IN 35 in a HIGH state and to apply clock CK0 40 to the input of the first latch 30. The static timing analysis tool then calculates the delay through each individual element as well as the cumulative delay from IN to each of the A-C-F-H-I-J (45, 60, 80, 92, 100, 110) signals as shown in Table 1. The notation “↑” in the table denotes a LOW-to-HIGH transition, and a “↓” denotes a HIGH-to-LOW transition. Depending upon the frequency of the clock signal, the cumulative delay of 55 ps through the circuit of the use case may or may not represent a condition that should be tested. For example, if the clock frequency is much less than 1/(55×10⁻¹² sec)≈18.2 GHz, then a 55 ps delay represents a small fraction of a clock cycle and therefore does not represent a condition requiring test. One example of a criterion that identifies delay conditions that do require test states that the delay should be less than 75% of a clock period. According to this criterion, the 55 ps delay of the present use case corresponds to a condition requiring test when the clock frequency is greater than about 13.6 GHz. This particular example is presented for illustrative purposes only and in no way is intended to limit the scope of the appended claims.

TABLE 1

| Transition | Delay | Cum Delay |
|---|---|---|
| CK0↑ to A↑ | 10 ps | 10 ps |
| A↑ to C↑ | 5 ps | 15 ps |
| C↑ to F↑ | 8 ps | 23 ps |
| F↑ to H↑ | 7 ps | 30 ps |
| H↑ to I↑ | 10 ps | 40 ps |
| I↑ to J↓ | 5 ps | 45 ps |
| Setup J↓ to CK1↑ | 10 ps | 55 ps |
| TOTAL DELAY | | 55 Ps |

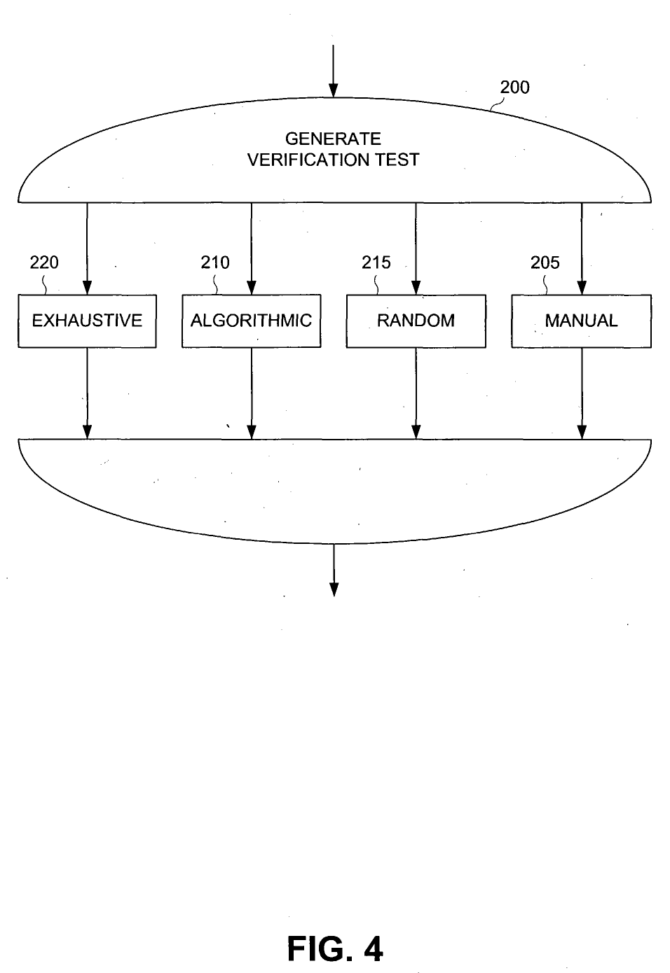

FIG. 4 is a flow diagram of a representative embodiment of a method for determining a design verification test. This variation of the method comprises generating a design verification test (step 200) using a test definition process selected from the group consisting of a manual test definition process (step 205), an algorithmic test definition process (step 210), a random test definition process (step 215), and an exhaustive test definition process (step 220).

A manual test definition process (step 205), according to one illustrative variation of the method, comprises inspecting the electrical circuit condition that requires test and then manually devising a test that exercises the electrical circuit condition. An algorithmic test definition process (step 210), according to another illustrative variation of the method, comprises executing a program that generates values for inputs according to an algorithm, thereby discovering a combination of inputs that exercises a specified electrical circuit condition. An exhaustive test definition process (step 220), according to still one more illustrative variation of the method, comprises generating all possible combinations of inputs and observing the result of the test with each such combination. If a worst case result is logged, then a test engineer is assured that the electrical circuit condition has been exercised. This method is appropriate when the number of inputs is not too large. When the number of inputs is large, then the time required to conduct an exhaustive test may be too long to be practical. In that instance, a random test definition process (step 215), according to yet another illustrative variation of the method, may be employed. A random test comprises generating random combinations of inputs and observing the result of the test with each such combination. Such an approach, on the average, may lead the test engineer to discover a test that exercises the required electrical condition in a shorter time than that required of an exhaustive test definition. The term “large number” of test inputs is really subjective in nature and is not central to the method taught here. In fact, the term large number can vary as a function of the efficiency of any particular implementation of the present method and the computing resources applied in the execution of the present method. What is important is that the method disclosed herein is adaptable to one or more of exhaustive and random techniques for the determination of a test definition.

As one example of a test definition that successfully exercises a required electrical condition, consider again the illustrative use case example of the circuit in FIG. 3. Static timing analysis of that circuit determined that the signal transitions listed in the first column of Table 1 represent an electrical condition that requires test when the clock frequency is sufficiently high. Once the condition has been determined, definition of a test comprises specifying a combination of inputs to the circuit that exercises the condition. In the example of FIG. 3, it was implicitly assumed that the signals B-D-E-G (50, 65, 70, 85) on inputs to AND gates 55, 90 and the OR gate 75 were held in either the HIGH or LOW state. The choice of HIGH or LOW for each signal depends upon which of these two states assures that the corresponding gate output actually undergoes a transition when the signal in the first column of Table 1 undergoes the indicated transition. For example, signal B 50 must be HIGH. (If it were LOW, then the output of the first AND gate 55 would not change when A 45 transitions from LOW to HIGH.) Using similar reasoning, signals D 65 and E 70 must be LOW; signal G 85 must be HIGH.

To summarize, a test that exercises the soft speed path electrical event just described should apply signals that assume the states listed in Table 2 during, for example, cycle N of the clock.

TABLE 2

Signal state
IN = 1
A↑
B = 1
C↑
D = 0
E = 0
F↑
G = 1
H↑
I↑
J↓

Construction of Table 2 is one step in one illustrative example of a manual test definition process (step 205). The resulting test definition declares that inputs IN 35, B 50, D 65, E 70, and G 85 should be applied to the circuit of FIG. 3 according to their values in Table 2. Asserting clock CK0 40 then exercises the required electrical condition.

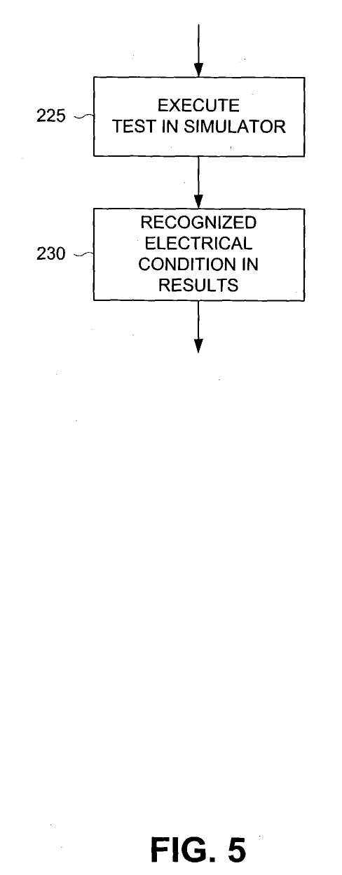

FIG. 5 is a flow diagram of a representative embodiment of a method for evaluating the effectiveness of a design verification test. According to this exemplary variation of the method, the test is executed in a simulator (step 225) and the results are analyzed to determine whether the required electrical condition is present (step 230). In the use case comprising the speed path example already described, the circuit of FIG. 3 would be executed in a simulator with inputs IN 35, B 50, D 65, E 70, and G 85 set according to their values in Table 2. Inspection of the results of the simulation then would reveal that the condition defined by Table 1 is exercised.

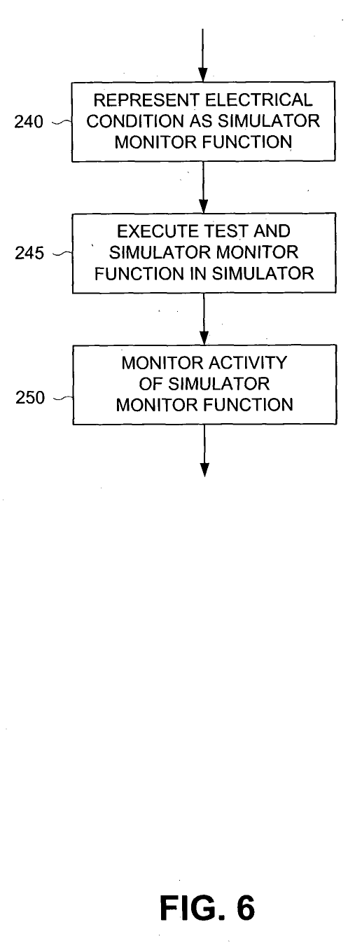

FIG. 6 is a flow diagram of an alternative embodiment of a method for evaluating the effectiveness of a design verification test. This alternative variation of the method comprises representing the electrical condition requiring test as a simulator monitor function (step 240). The simulator then executes the test and the monitor function (step 245). Monitoring the activity of the simulator monitor function (step 250) indicates when the required condition has been executed. As one illustrative example of such a simulator monitor function that applies to the speed path use case already introduced, a function that takes on the value 1 when the conditions of the first column are true and that takes on the value zero otherwise is defined. Executing the test and the monitor function in a simulator (step 245) then comprises simulating the circuit and, as the simulation progresses, passing the values in the first column of Table 1 to the monitor function. The activity of the monitor function can be monitored by noting when its value is 1 (i.e. “true”).

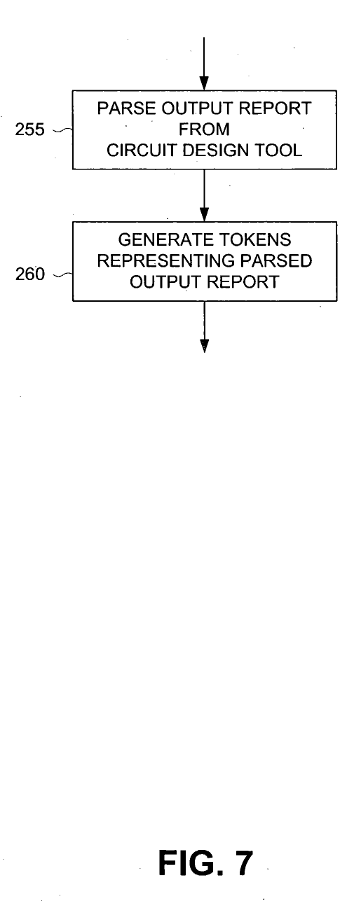

FIG. 7 is a flow diagram of a representative embodiment of a method of receiving design information. This example of the present method comprises parsing an output report from a circuit design tool (step 255) and generating tokens that represent the parsed output report (step 260). Referring again to the use case introduced in the discussion of FIG. 3, one form of an output report takes a form very similar to Table 1. One particular method of parsing such a table comprises ignoring white space like spaces, tabs, and line feeds. This method further comprises recognizing strings of characters such as “<name>↑”, “<name>↓”, “to”, “Setup”, “:”, numerical digits, and the like where <name> is “CK0”, “A”, and so on. Each such recognized character string then is represented by a token. This method of receiving design information converts the design information to a standardized form that simplifies methods of further analyzing the design information.

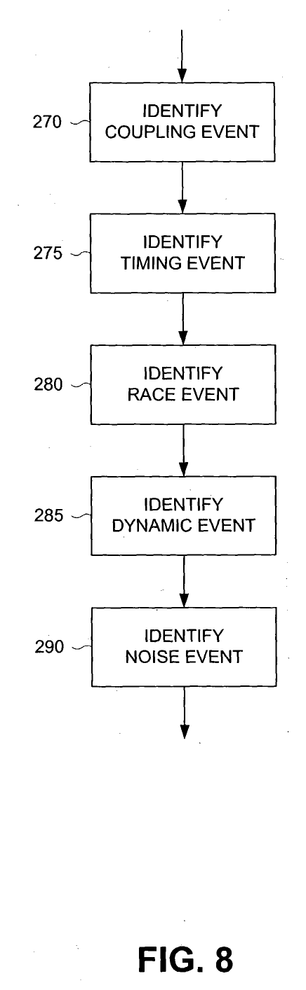

FIG. 8 is a flow diagram of a representative embodiment of a method for identifying an electrical circuit condition. The present method is applicable to a variety of types of electrical circuit conditions that may require test. One particular variation of the method identifies a coupling event (step 270). Another variation of the method identifies a timing event (step 275) or a race event (step 280). Timing and race events may be identified using the method introduced in the discussion of FIG. 3. Yet another variation of the method identifies a dynamic hazard (step 285). In one particular variation of the method, a noise event is identified (step 290) when one or more coupling events occur in combination with one or more other effects such as timing so that the cause of the event cannot easily be isolated. In one illustrative variation of the method, a circuit designer recognizes potential problem signals in the design as noise events, thereby identifying conditions requiring test.

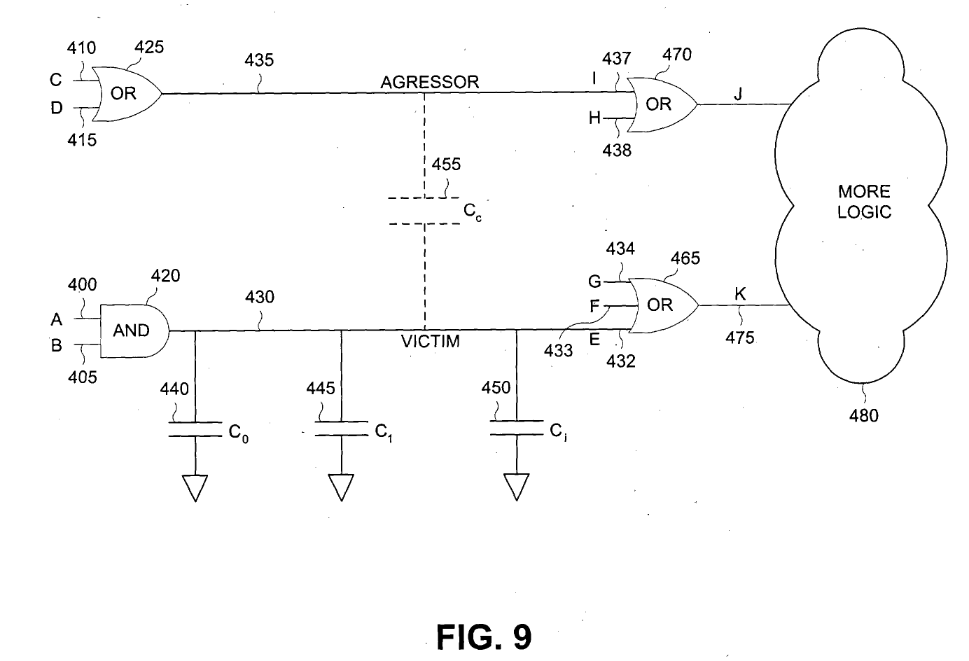

FIG. 9 is a schematic diagram of one representative electrical circuit use case that illustrates another electrical circuit condition requiring test. It should be noted that this, and other use cases herein presented are provided for the purpose of illustration and are not intended to limit the scope of the claims appended hereto. The condition in this use case is a coupling event arising from the physical proximity of two wires, a first wire 430 and a second wire 435, the two wires being capacitively coupled by parasitic capacitance C_{c} 455. In one example mode of operation of this circuit, the parasitic capacitive coupling causes an aggressor signal 1437 to disturb the level of a victim signal E 432, thereby resulting in a “bounce” in the value of signal K 475. Such a condition is one that requires test in this use case.

In greater detail, the circuit of FIG. 9 comprises an AND gate 420 driven by signals A 400 and B 405. The characteristics of the AND gate 420 include output capacitance Cₒ 440. The circuit further comprises a first OR gate 425 driven by signals C 410 and D 415. The output of the AND gate 420 is connected to one input of a second OR gate 465 by a wire 430, thereby producing a signal E 432 (the victim) at the input of the second OR gate 465. The characteristics of the second OR-gate 465 include input capacitance Cᵢ 450 associated with signal E 432. Signals F 433 and G 434 also serve as inputs to the second OR gate 465. The output of first OR gate 425 is connected to one input of a third OR gate 470, thereby producing a signal 1437 (the aggressor). Signal H 438 also serves as an input to the third OR gate 470. In one example of this use case, the drive characteristics of the first OR gate 425, the receiver characteristics of the third OR gate, and other characteristics of the connection between first OR gate 425 and third OR gate 470 are known. Knowing these characteristics, a circuit design tool, such as a circuit simulator, can determine edge characteristics (e.g., the rise time) of aggressor signal 1437. Continuing with the present use case, the receiver characteristics of the second OR gate 465 also are known. These characteristics, again in the present use case, comprise a threshold, T, related to capacitance on the input to second OR gate 465. A circuit design tool, such as a circuit simulator, calculates a capacitance ratio defined by

$$R = \frac{{C}_{c}}{{C}_{o} + {C}_{1} + {C}_{i} + {C}_{c}} .$$

The circuit design tool further calculates the ratio, R/T, and includes the R/T ratio in its report to the user. By scanning the report, the user can select values of the R/T ratio that exceed, for example, 90%, to identify a coupling event requiring test. In the present use case, the output of the circuit design tool contains a line of the form shown in Table 3 illustrating a situation where aggressor node I 437 affects victim note E 432 on the Nth clock cycle. The R/T ratio in this instance is 0.92, thereby identifying a coupling event that requires test.

TABLE 3

| Clock Cycle | Victim node | Aggressor node | R/T ratio |
|---|---|---|---|
| N | E | I | 92% |

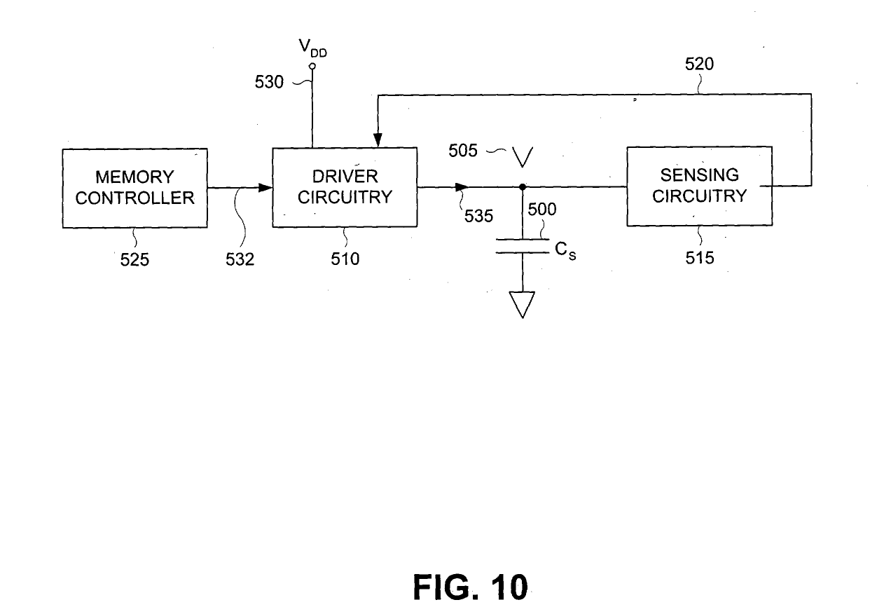

FIG. 10 is a schematic diagram of yet another representative electrical circuit use case that illustrates an electrical circuit condition requiring test. This schematic diagram illustrates a dynamic hazard, referring to a fault whereby a value that is designed to hold its value during a given time interval changes significantly during the given time interval. In one use case illustrated in FIG. 10, a storage capacitor Cs 500 stores a voltage V 505 that assumes, on each clock cycle, one of two nominal values approximating either zero volts or V_{DD} volts where V_{DD} 530 is a reference supply voltage. Storage devices of this type form the basis of dynamic random access memory (DRAM). In normal operation, a memory controller 525 applies a memory write signal 532 to driver circuitry 510 according to whether the value of V 505 should be zero or V_{DD} volts. Driver circuitry 510 supplies a charging current 535 to charge Cs 500 to the value determined by the memory write signal 532. In the absence of parasitic effects, the value of V 505 would remain constant until changed by a new memory write signal 532. In practice, however, the value of V 505 does “leak away” after some time. To compensate for this normal leakage, sensing circuitry 515, from time to time at a rate called the “refresh rate”, senses the value of V 505 to determine whether V 505 is nearer to zero volts or to V_{DD} volts and, accordingly, provides feedback 520 to driver circuitry 510. Driver circuitry 510 then “refreshes” the value of V 505 by supplying a value of charging current 535 sufficient to restore V 505 to either zero or V_{DD} volts according to the feedback signal 520. In one illustrative example of the present use case, V 505 is designed to hold at a level of at least 80% of reference voltage V_{DD} for at least 10 clock cycles. In that same example, a circuit design tool, using information about the specifics of the driver circuitry 510, sensing circuitry 515, and the storage capacitor Cs 500, determines that V 505 decays to about 82% of V_{DD} in 10 clock cycles. Because 82% is near the critical value of 80%, such an event appears in the report generated by the circuit design tool and is identified as a marginal condition that requires test.

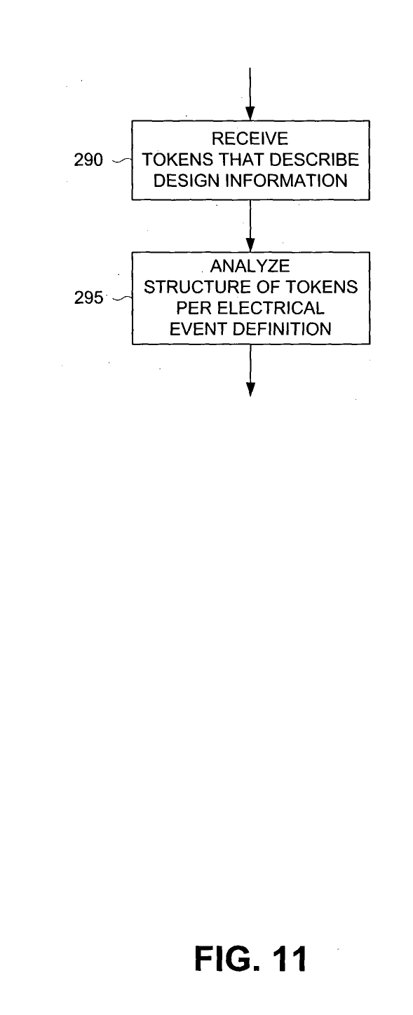

FIG. 11 is a flow diagram of an alternative representative embodiment of a method for identifying an electrical circuit condition that requires test. This alternative variation of the method is applicable when tokens have been generated that represent the information in an output report produced by a circuit design tool. According to this alternative variation, tokens are received that describe the design information (step 290). The structure of the set of tokens then is analyzed in accordance with a pre-established electrical event definition (step 295). One use case that illustrates this alternative variation of the method applies to analysis of information like that represented in Table 3. Tokens representing the clock cycle, victim node identifier, aggressor node identifier, and R/T ratio are received (step 290). According to the present use case acceptable values for the R/T ratio are those exceeding 90%. According to another aspect of the present use case, values of R/T between 90% and 93% are defined to be marginal. Analysis of the tokens therefore identifies a numerical value of 0.92 for the R/T token as a marginal value, thus identifying an electrical condition that requires test. It should be noted that these use case examples are provided here to illustrate the present method and are not to be used to limit the scope of the claims appended hereto.

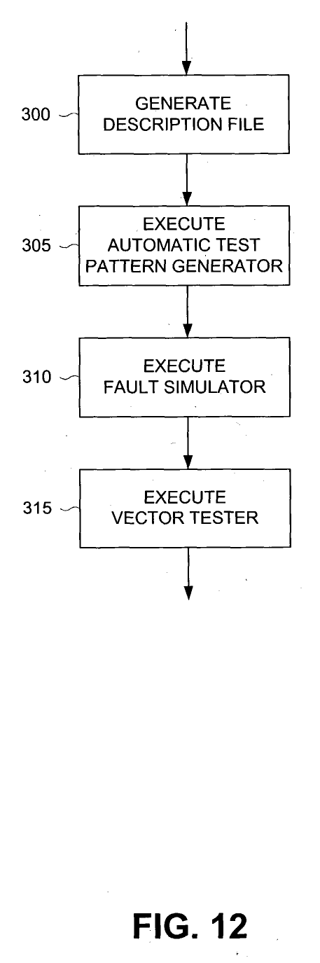

FIG. 12 is a flow diagram of a representative embodiment of a method for evaluating the effectiveness of a design verification test. According to this variation of the method, design information received from a circuit design tool takes the form of a description file (step 300). In one particular variation of the method, the description file is readable by one or more of an automatic test pattern generator, a fault simulator, and a vector tester. In one exemplary variation of the method, an automatic test pattern generator is executed (step 305) using the description file as input. In another exemplary variation of the method, a fault simulator is executed (step 310) with the description file as input. In yet another exemplary variation of the method, a vector tester is executed (step 315) with the description file as input. The speed path example introduced in the discussion of FIG. 3 illustrates one form of the method. In this example, a static timing analysis tool produces the information in Table 1 and passes the information to a text processor that generates a machine-readable description file according to the information. An automatic test pattern generator reads the description file and generates a test pattern comprising values for IN 35, B 50, D 65, E 70, and G 85 according to the circuit design and the description file.

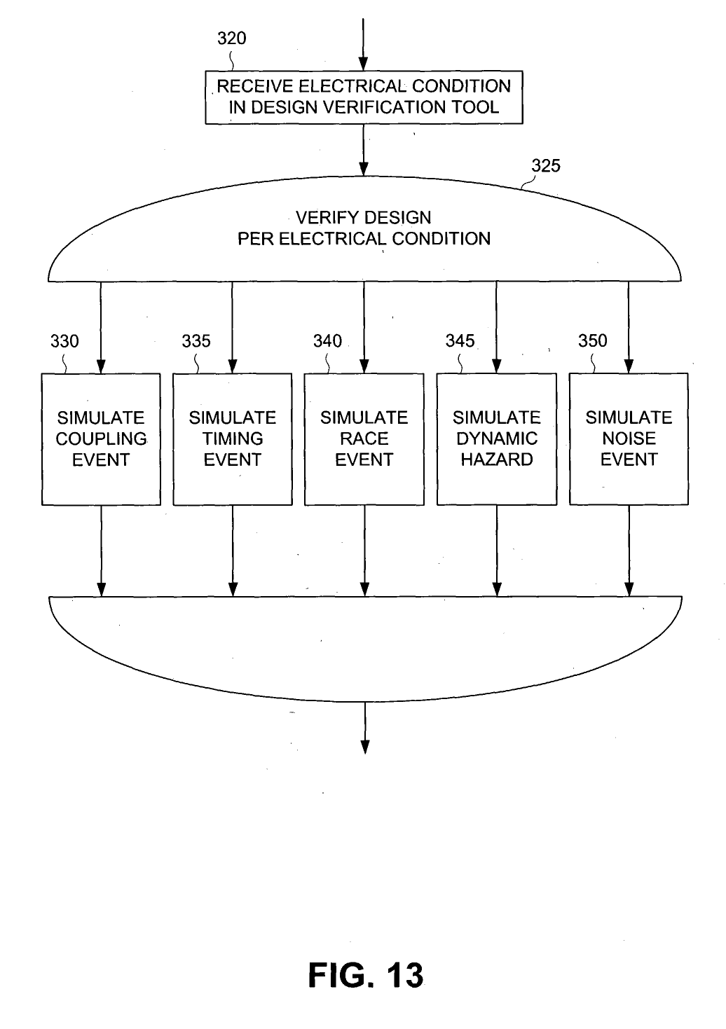

FIG. 13 is a flow diagram of a representative embodiment of a method for verifying the design of an electronic circuit based upon an electrical circuit condition. According to this variation of the method, an identified electrical circuit condition that requires test is received in a design verification tool (step 320). The design of the electronic circuit then is verified by simulating the design, taking care to assure that the electrical circuit condition is exercised (step 325). In one variation of the method, simulating a coupling event (step 330) of the type described in the description of FIG. 9 verifies the design. In another variation of the method, simulating a timing event (step 335) or a race event (step 340) as described in the description of FIG. 3 verifies the design. In yet another variation of the method, simulating a dynamic hazard (step 345) as described in the description of FIG. 10 verifies the design. In yet one more variation of the method, simulating a noise event (step 350) as described in the description of FIG. 8 verifies the design.

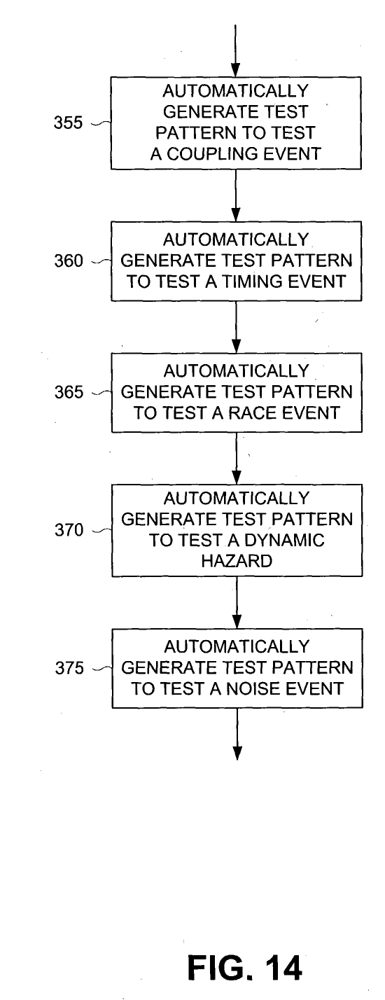

FIG. 14 is a flow diagram of a representative embodiment of one alternative method for verifying the design of an electronic circuit based upon an electrical circuit condition. One variation of the method comprises automatically generating a test pattern to test a coupling event (step 355). Another variation of the method comprises automatically generating a test pattern to test a timing event (step 360). Still another variation of the method comprises automatically generating a test pattern to test a race event (step 365). Yet another variation of the method comprises automatically generating a test pattern to test a dynamic hazard (step 370). Still one more variation of the method comprises automatically generating a test pattern to test a noise event (step 375).

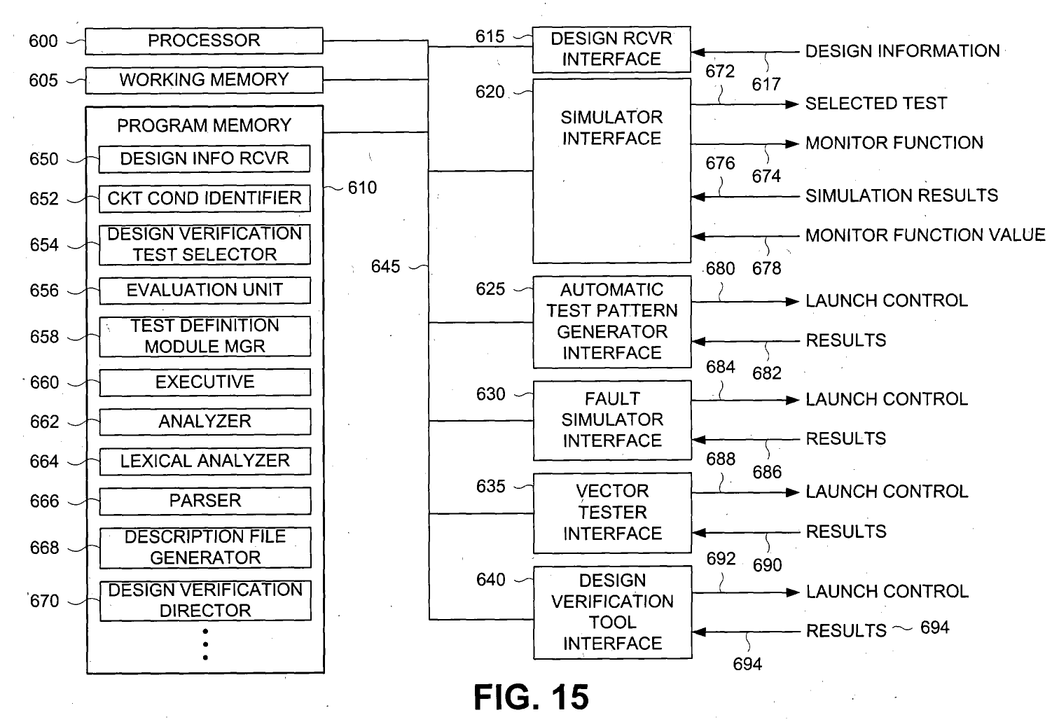

FIG. 15 is a block diagram of a representative embodiment of a computing platform that is capable of characterizing an electronic circuit. This exemplary embodiment comprises a processor 600, working memory 605, program memory 610, and a design receiver interface 615. According to one alternative embodiment, the computing platform further comprises a simulator interface 620. According to yet another alternative embodiment, the computing platform further comprises an automatic test pattern generator interface 625. According to yet another alternative embodiment, the computing platform further comprises a fault simulator interface 630. According to yet another alternative embodiment, the computing platform further comprises a vector tester interface 635. And, according to yet another alternative embodiment, the computing platform further comprises a design verification tool interface 640. All of these elements, irrespective of embodiment, are interconnected by a system bus 645. The program memory 610 in this embodiment has stored therein instruction sequences that, when loaded into working memory 605 and executed by the processor 600, minimally cause the processor 600 to implement functional modules more particularly described infra. The program memory 610 contains one or more instruction sequences identified in this example embodiment as design information receiver 650, circuit condition identifier 652, design verification test selector 654, evaluation unit 656, test definition module manager 658, executive 660, analyzer 662, lexical analyzer 664, parser 666, description file generator 668, and design verification director 670. Again, each of the aforementioned instruction sequences defines a like-named functional module that is described in more detail infra.

The design receiver interface 615 in this embodiment is capable of receiving an electronic representation of a design 617 and is capable of communicating the electronic representation of the design to the system bus 645 whence it can be received and manipulated by the processor 600. The simulator interface 620 in one embodiment services two outputs: a selected test output 672 and a monitor function output 674. The simulator interface 620 also services two inputs: a simulation results input 676 and a monitor function value input 678. These outputs 672, 674 and inputs 676, 678 provide means by which the computing platform is able to communicate with an external simulator. The automatic test pattern generator interface 625 in another embodiment services a launch control output 680 and a results input 682. This output 680 and input 682 provide means by which the computing platform is able to communicate with an external automatic test pattern generator. The fault simulator interface 630 according to one alternative embodiment services a launch control output 684 and a results input 686. This output 684 and input 686 provide means by which the computing platform is able to communicate with an external fault simulator. The vector tester interface 635 in yet another embodiment services a launch control output 688 and a results input 690. This output 688 and input 690 provide means by which the computing platform is able to communicate with an external vector tester. The design verification tool interface 640 in an alternative embodiment services a launch control output 692 and a results input 694. This output 692 and input 694 provide means by which the computing platform is able to communicate with an external design verification tool.

The various embodiments of a computing platform illustrated in FIG. 15 are provided to illustrate the construction of an apparatus capable of characterizing electronic circuits according to the present method. The scope of the appended claims is not intended to be limited to any one of these exemplary embodiments.

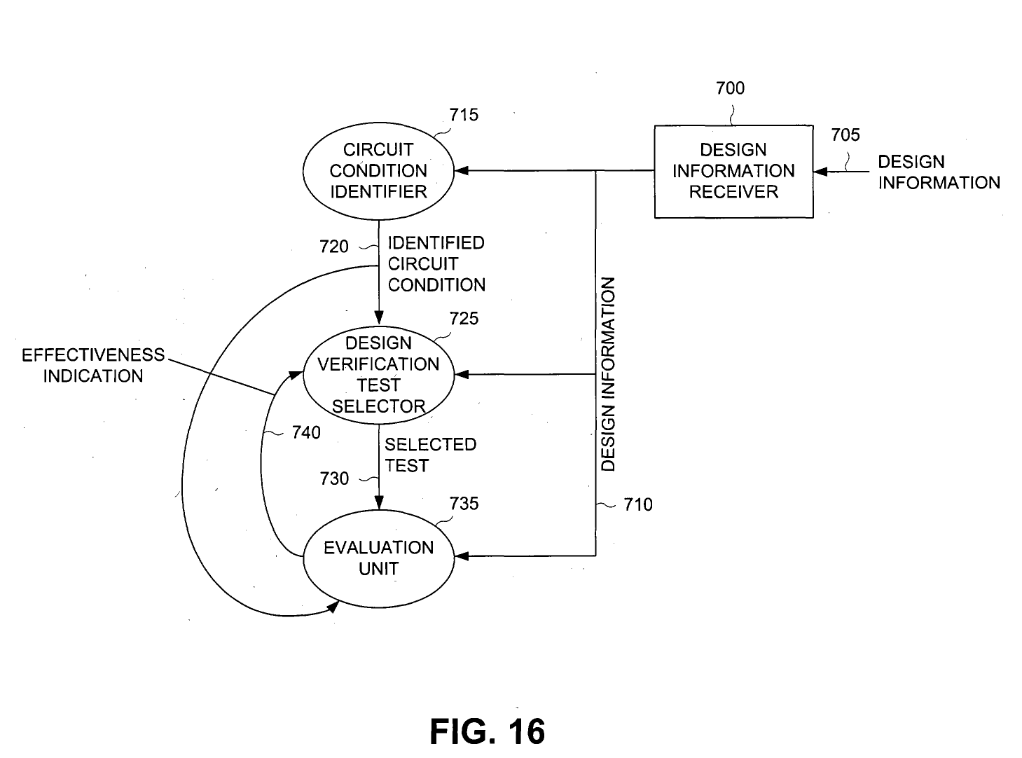

FIG. 16 is a data flow diagram that illustrates the operation of a representative embodiment of a device that is capable of characterizing an electronic circuit. This illustrative embodiment comprises a design information receiver 700 capable of receiving design information from the design receiver interface 615. This illustrative embodiment further comprises a circuit condition identifier module 715, a design verification test selector module, and an evaluation unit 735. According to one illustrative embodiment, each of these modules comprises an instruction sequence that is stored in the program memory 610 and carries out its function when executed by the processor 600. Design information 710 acquired by the design information receiver 700 is passed to the circuit condition module 715, the design verification test selector module 725, and the evaluation unit 735. The circuit condition identifier 715 is capable of identifying in the design information 710 an electrical circuit condition 720 that requires test. According to one exemplary embodiment, the circuit condition identifier 715 is capable of identifying in the design information 710 at least one of a noise event, a coupling event, a timing event, a race event and a dynamic hazard. The identified circuit condition 720 is communicated to the design verification test selector module 725 that is capable of selecting a design verification test. The identified circuit condition 720 also is communicated to the evaluation unit 735. The selected design verification test 730 is communicated to the evaluation unit 735 that is capable of evaluating the effectiveness of the selected test. An indication 740 of the effectiveness of the test is passed to the design verification test selector. In one illustrative embodiment of the device the design verification test selector is capable of selecting a different test when the first-selected test 730 is not effective.

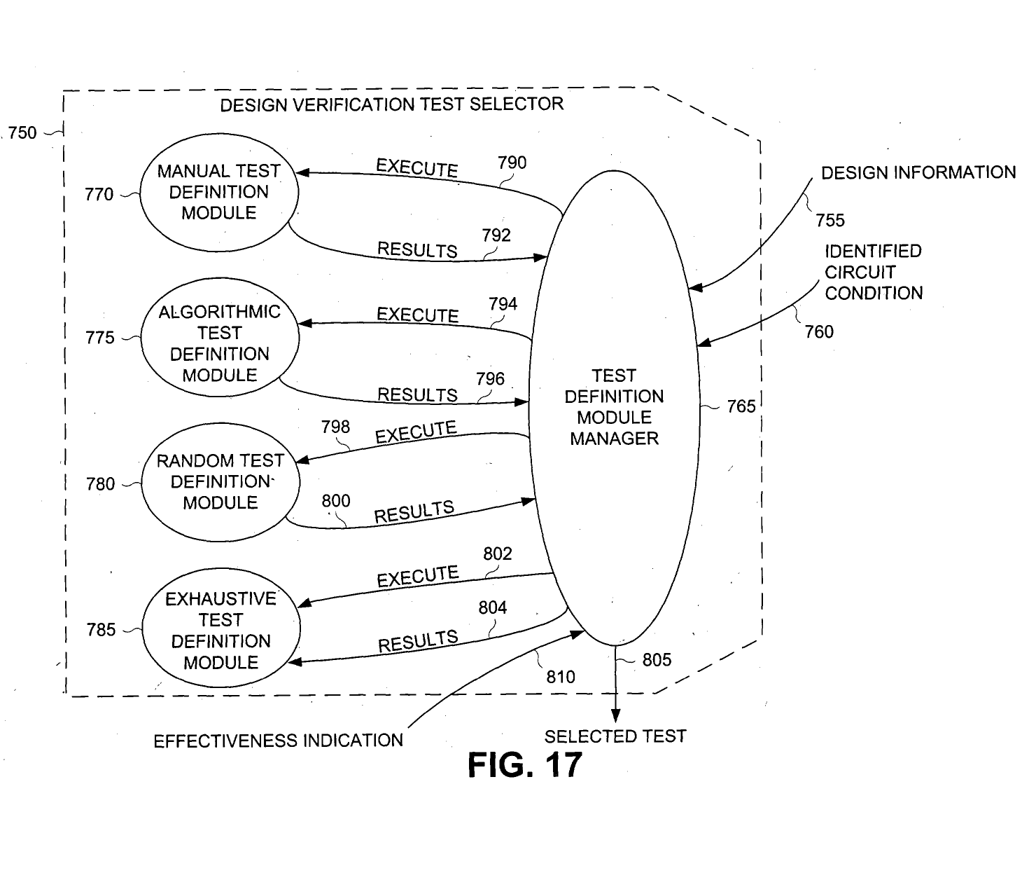

FIG. 17 is a data flow diagram that illustrates the operation of a representative embodiment of a design verification test selector 750. This illustrative embodiment comprises a test definition module manager 765 capable of initiating the execution of a test definition module. According to one embodiment, the test definition module is selected from a group consisting of a manual test definition module 770, an automated test definition module 775, a random test definition module 780, and an exhaustive test definition module 785. Initiation of a test definition module is accomplished by means of respective execute signals 790, 794, 798, and 802 corresponding to the various types of test definition modules in said group of modules. According to one illustrative embodiment, each of these modules and the test definition module manager 765 comprise an instruction sequence that is stored in the program memory 610 and carries out its function when executed by the processor 600. The test definition module manager 765 further is capable of receiving results from the execution of any of the aforementioned modules by means of respective results paths 792, 796, 800, and 804. According to one exemplary mode of operation of the design verification test selector 750, design information 755 and an identified circuit condition 760 are received by the test definition module manager 765. The test definition module manager launches one of the test definition modules 770, 775, 780, 785 and presents a selected test 805 according to the result returned by the previously launched test definition module through one of the paths 792, 796, 800, 805. In one particular operating mode, an effectiveness indication 810 is received in response to presentation of the selected test 805. In the event that the effectiveness indication reflects a non-effective test selection (i.e. the selected test did not exercise the circuit condition), the design verification test selector 750 continues operation by selecting a different test in accordance with the teachings of the present method.

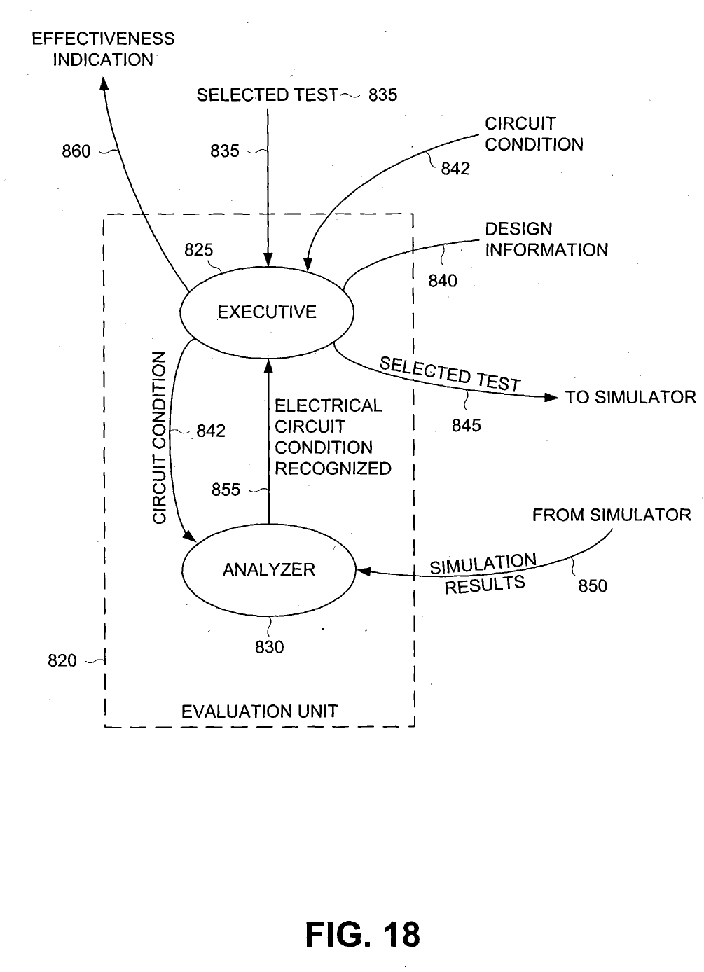

FIG. 18 is a data flow diagram that illustrates the operation of a representative embodiment of an evaluation unit 820. This example embodiment comprises an executive module 825 and an analyzer module 830. According to one illustrative embodiment, each of these modules comprises an instruction sequence that is stored in the program memory 610 and carries out its function when executed by the processor 600. According to one typical mode of operation, the executive module 825 receives design information 840, receives an electrical circuit condition 842 that requires test, and receives an associated design verification test 835. The executive module 825 conveys the design verification test 835 to a simulator and communicates the circuit condition 842 to the analyzer module 830. The analyzer module 830 receives corresponding simulation results 850. The analyzer 830 is capable of determining whether the electrical circuit condition 842 appears in the simulation results 850. If the electrical circuit condition 842 appears in the simulation results, then the analyzer module 830 informs the executive module 825 by asserting the electrical circuit condition recognized signal 855. The executive module 825 forwards this signal as an indication of test effectiveness to the design verification test selector.

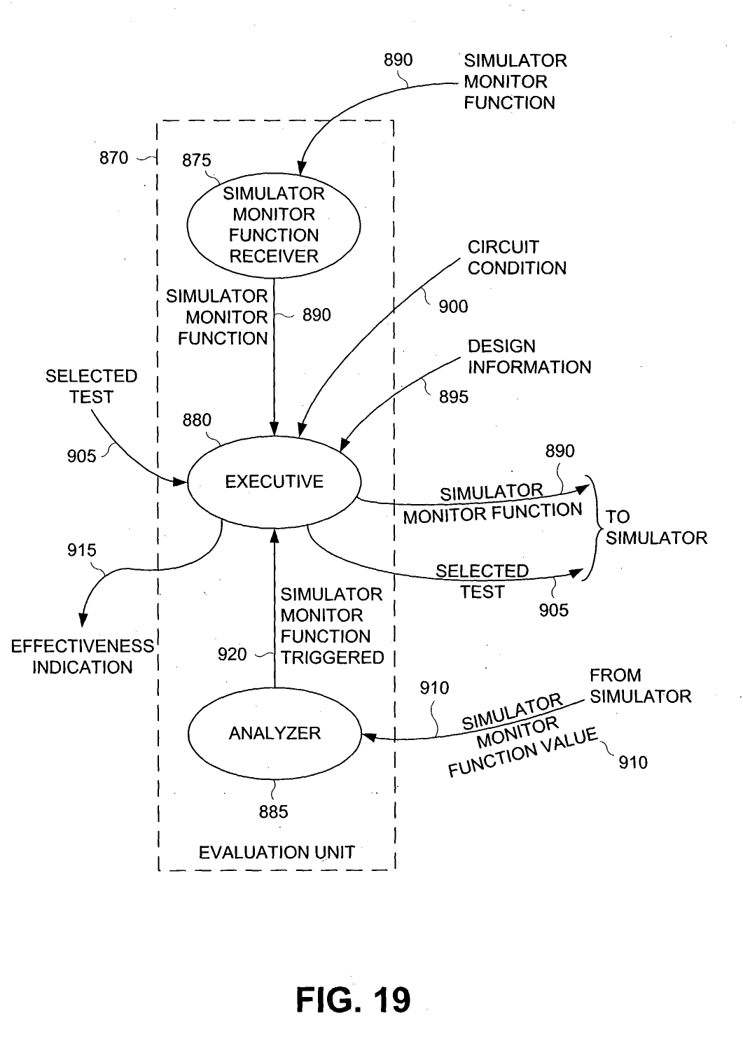

FIG. 19 is a data flow diagram that illustrates the operation of an alternative representative embodiment of an evaluation unit 870. This particular example embodiment comprises a simulator monitor function receiver module 875 capable of receiving a simulator monitor function 890, an executive module 880, and an analyzer module 885. According to one illustrative embodiment, each of these modules comprises an instruction sequence that is stored in the program memory 610 and carries out its function when executed by the processor 600. According to one illustrative mode of operation of this embodiment, the simulator monitor function receiver receives a simulator monitor function 890 and passes it to the executive module 880. The executive module 880 receives the simulator monitor function 890 and passes it to an external simulator. The executive module 880 further receives design information 895, a circuit condition requiring test 900, and a selected test 905. The executive module 880 passes the selected test 905 to the simulator. The analyzer module 885 receives from the simulator a value 910 of the simulator monitor function. According to the monitor function value 910, the analyzer 885 determines whether the simulator monitor function has been triggered. If the simulator monitor function has been triggered, then the analyzer 885 asserts the simulator monitor function triggered signal 920. This indicates that the circuit condition was exercised by the selected test and is forwarded to the design verification test selector as an efficacy indicator.

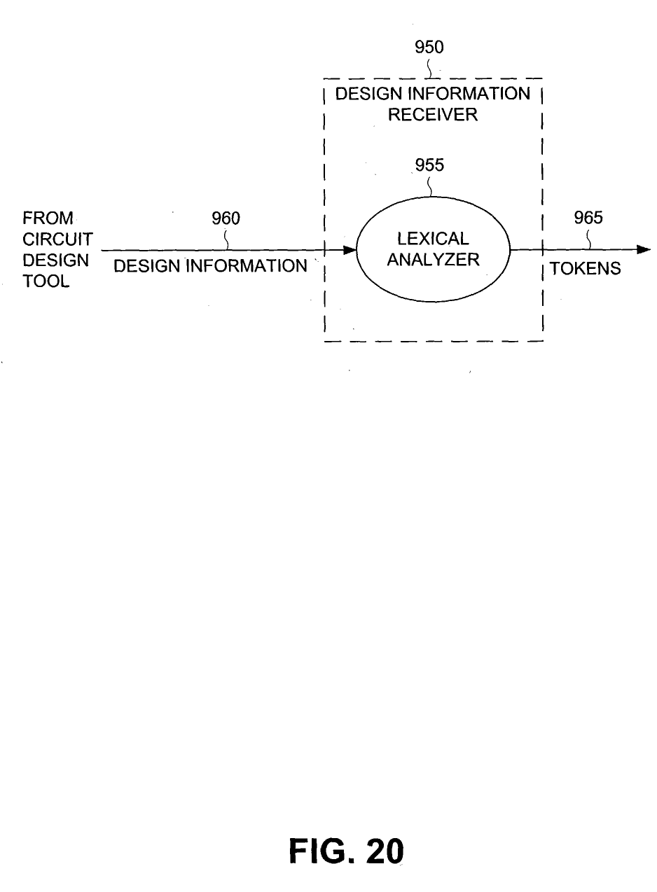

FIG. 20 is a data flow diagram that illustrates the operation of a representative embodiment of a design information receiver 950. This embodiment comprises a lexical analyzer 955 capable of analyzing design information 960 received from an external circuit design tool. According to one illustrative embodiment, the lexical analyzer 955 comprises an instruction sequence that is stored in the program memory 610 and carries out its function when executed by the processor 600. The lexical analyzer 955 removes extraneous information and converts the essential design information into tokens 965 that are presented to other function modules according to the present description.

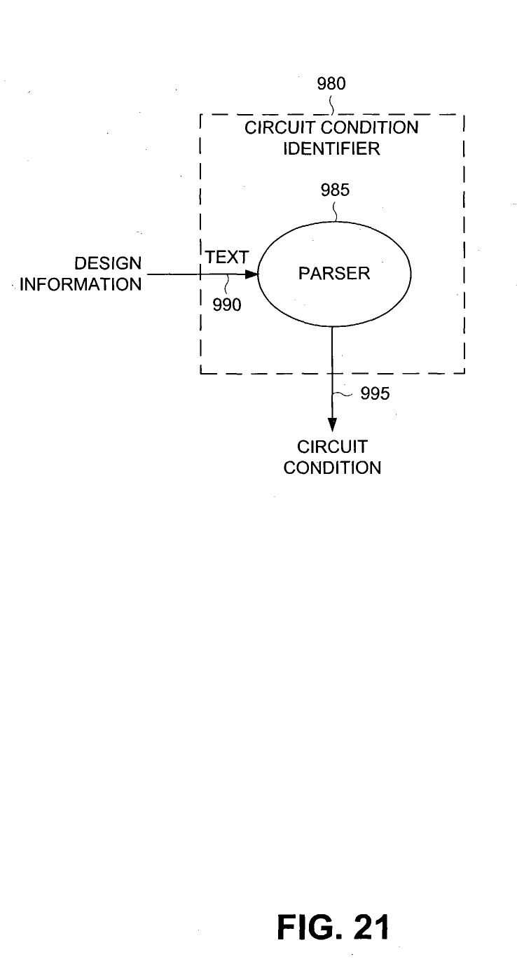

FIG. 21 is a data flow diagram that illustrates the operation of a representative embodiment of a circuit condition identifier 980. This embodiment comprises a parser 985 capable of analyzing design information that, according to one illustrative example embodiment, is received from a design information receiver. According to one illustrative embodiment, the parser 985 comprises an instruction sequence that is stored in the program memory 610 and carries out its function when executed by the processor 600. The parser 985 further is capable of detecting in the analyzed text 990 a circuit condition 995 requiring test and of presenting the detected circuit condition 995 to other modules according to the present description. According to one exemplary embodiment, the parser 985 is capable of identifying in the design information at least one of a noise event, a coupling event, a timing event, a race event and a dynamic hazard.

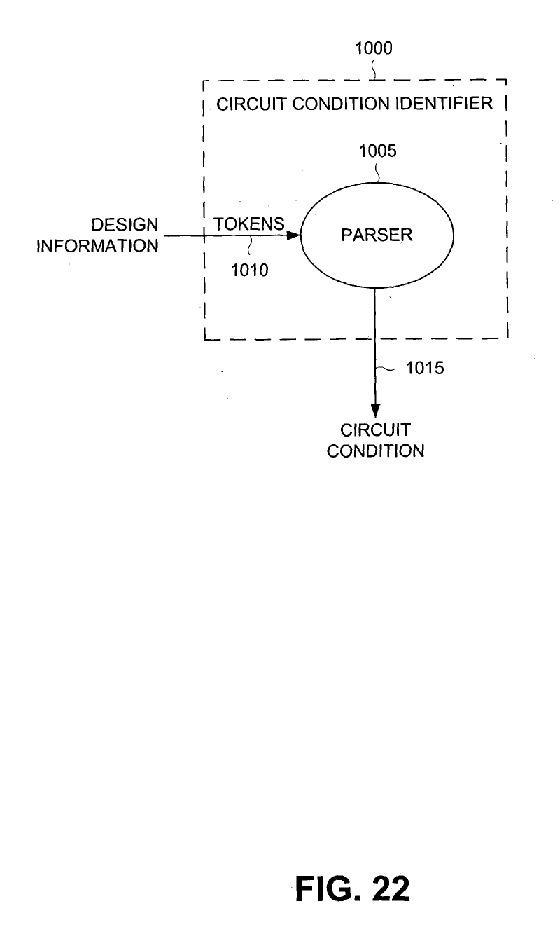

FIG. 22 is a data flow diagram that illustrates the operation of an alternative representative embodiment of a circuit condition identifier 1000. This alternative embodiment comprises a parser 1005 capable of extracting a circuit condition 1015 that requires test from received tokens 1010 representative of design information. The parser 1005 further is capable of presenting the identified circuit condition 1015. According to one illustrative embodiment, the parser 1015 comprises an instruction sequence that is stored in the program memory 610 and carries out its function when executed by the processor 600.

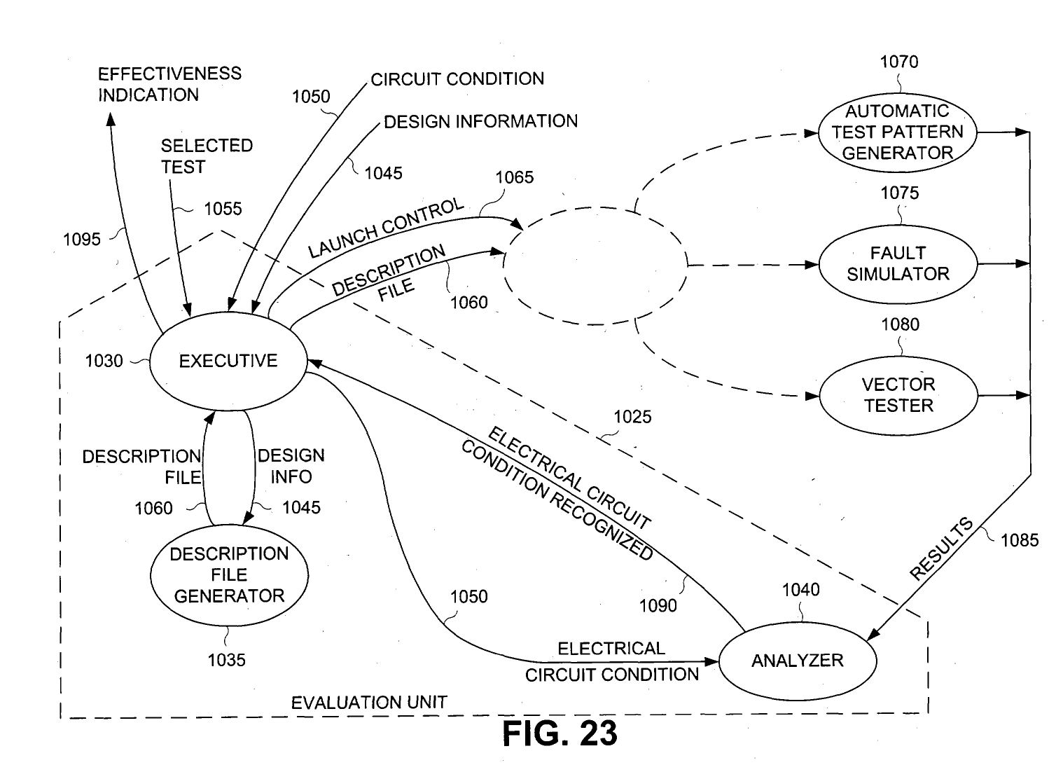

FIG. 23 is a data flow diagram that illustrates the operation of another alternative representative embodiment of an evaluation unit 1025. This alternative embodiment comprises an executive module 1030, a description file generator module 1035, and analyzer module 1040. The executive module 1030 is capable of receiving design information 1045, a circuit condition that requires test 1050, and a selected test 1055. According to one illustrative embodiment, each of these modules comprises an instruction sequence that is stored in the program memory 610 and carries out its function when executed by the processor 600. According to one exemplary mode of operation, the executive module 1030 passes the design information 1045 to the description file generator 1035 and passes the electrical circuit condition 1050 that requires test to the analyzer module 1040. The description file generator is capable of generating a description file that is readable by an automatic test pattern generator 1070, a fault simulator 1075, or a vector tester 1080. The description file is representative of the design information 1045. In one representative embodiment, the description file generator passes a generated description file 1060 to the executive module 1030. The executive module 1030 then launches, by means of a launch control signal 1065, operation of an external device chosen from the group consisting of the automatic test pattern generator 1070, the fault simulator 1075, and the vector tester 1080. The executive module 1030 also passes the description file 1060 to the launched device. Results 1085 from the launched device are received by the analyzer 1040 that passes an electrical circuit condition recognized signal 1090 to the executive module 1030 when the electrical circuit condition 1050 is recognized in the results 1085. In one particular mode of operation, the executive module 1030 generates an effectiveness indication 1095 according to the state of the electrical circuit condition recognized signal 1090 according to the present method. This is used to drive the selection of a different test.

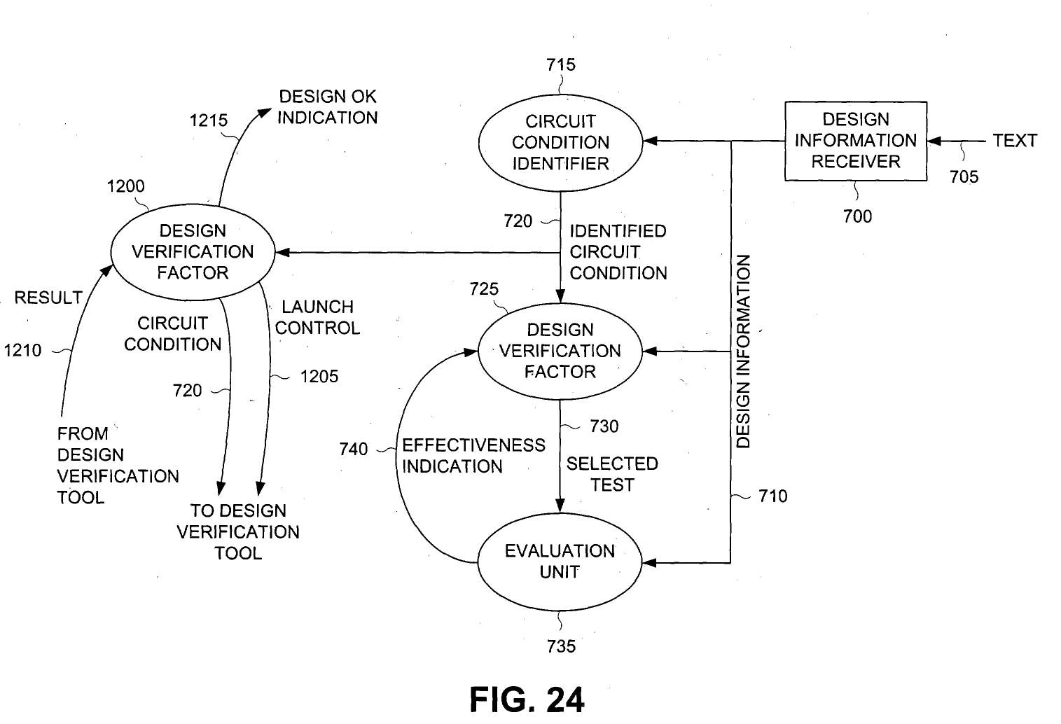

FIG. 24 is a data flow diagram that illustrates the operation of an alternative representative embodiment of a device that is capable of characterizing an electronic circuit. This embodiment comprises a design information receiver 700, a circuit condition identifier module 715 that generates an identified circuit condition 720, a design verification test selector module 725, and an evaluation unit 735 all of which function as described supra. The embodiment further comprises a design verification director module 1200. The design verification director module 1200 receives the identified circuit condition 720, directs the circuit condition 720 to an external design verification tool, and launches operation of the design verification tool by means of a launch control signal 1205. The design verification director 1200 receives a result 1210 from the design verification tool and asserts a design OK indication 1215 when the identified circuit condition 720 is not detected in the result 1210.

According to yet another embodiment, computer executable instruction sequences for the design information receiver 650, the circuit condition identifier 652, the design verification test selector 654, the evaluation unit 656, the test definition module manager 658, the executive 660, the analyzer 662, the lexical analyzer 664, the parser 666, the description file generator 668, and the design verification director 670 as well as computer executable instruction sequences for the manual test definition module 770, the algorithmic test definition module 775, the random test definition module 780, the exhaustive test definition module 785, and the simulator monitor function receiver 875, are imparted onto computer readable media. Examples of such media include, but are not limited to, random access memory, read-only memory (ROM), CD ROM, floppy disks, and magnetic tape. These computer readable media, which alone or in combination can constitute a stand-alone product, can be used to convert a general-purpose computing platform into a device for characterizing an electronic circuit according to the teachings presented herein. Accordingly, the claims appended hereto are to include such computer readable media imparted with such instruction sequences that enable execution of the present method and all of the teachings afore described.

Alternative Embodiments

While the present method, apparatus and software have been described in terms of several exemplary embodiments, it is contemplated that alternatives, modifications, permutations, and equivalents thereof will become apparent to those skilled in the art upon a reading of the specification and study of the drawings. It is therefore intended that the true spirit and scope of the appended claims include all such alternatives, modifications, permutations, and equivalents.

1. A method for characterizing an electronic circuit comprising:
receiving design information from a circuit design tool;
identifying an electrical circuit condition that requires test based on the design information;
determining a design verification test;
evaluating the effectiveness of the design verification test in exercising the electrical circuit condition; and
determining a second design verification test and also evaluating the effectiveness of the second design verification test in exercising the electrical circuit condition when the first design verification test does not effectively exercise the electrical circuit condition.

2. The method of claim 1 wherein determining a design verification test comprises:
generating a design verification test using one or more of a manual test definition process, an algorithmic test definition process, a random test definition process and an exhaustive test definition process.

3. The method of claim 1 wherein evaluating the effectiveness of the design verification test comprises:
executing the design verification test in a simulator; and
recognizing the presence of the electrical circuit condition in the simulator results.

4. The method of claim 1 wherein evaluating the effectiveness of the design verification test comprises:
representing the electrical condition in a simulator monitor function;
executing the design verification test and the simulator monitor function in a simulator; and
monitoring the activity of the simulator monitor function.

5. The method of claim 1 wherein receiving design information comprises:
parsing an output report from a circuit design tool; and
generating tokens representing the parsed output report.

6. The method of claim 1 wherein identifying an electrical circuit condition comprises one or more of identifying a noise event, identifying a coupling event, identifying a timing event, identifying a race event and identifying a dynamic hazard.

7. The method of claim 1 wherein identifying an electrical circuit condition comprises:
receiving tokens descriptive of the design information; and
analyze the structure of the tokens in accordance with a pre-established electrical event definition.

8. The method of claim 1 wherein evaluating the effectiveness of the design verification test comprises:
generating a description file readable by one or more of an automatic test pattern generator, a fault simulator, and a vector tester; and
causing one or more of an automatic test pattern generator, a fault simulator, and a vector tester to be executed using said generated description file as an input.

9. The method of claim 1 further comprising:
receiving the electrical circuit condition in a design verification tool; and
verifying the design of the electronic circuit based on the electrical circuit condition.

10. The method of claim 9 wherein verifying the design comprises simulating one or more of a noise event, a coupling event, a timing event, a race event, and a dynamic hazard.

11. The method of claim 9 wherein verifying the design comprises automatically generating a test pattern for testing one or more of a noise event, a coupling event, a timing event, a race event, and a dynamic hazard.

12. An apparatus for characterizing an electronic circuit comprising:
design information receiver capable of receiving design information;
circuit condition identifier capable of identifying an electrical circuit condition in the design information that requires test;
design verification test selection unit capable of selecting a first design verification test; and
evaluation unit capable of evaluating the effectiveness of the first selected design verification test in exercising the identified circuit condition and wherein the design verification test selection unit is capable of selecting a second design verification test when the evaluation unit determines that the first selected design verification test is ineffective in exercising the identified circuit condition and wherein the evaluation unit is capable of evaluating the effectiveness of the second selected design verification test.

13. The apparatus of claim 12 wherein the design verification test selection unit comprises one or more of a manual test definition module, an automated test definition module, a random test definition module, and an exhaustive test definition module.

14. The apparatus of claim 12 wherein the evaluation unit comprises:
executive module that conveys the design verification test to a simulator; and
analyzer module that receives results from the simulator and issues a signal when the electrical circuit condition is recognized in said simulator results.

15. The apparatus of claim 12 wherein the evaluation unit comprises:
simulator monitor function receiver capable of receiving a simulator monitor function;
executive module that conveys the design verification test and the received simulator monitor function to a simulator; and
analyzer module that issues a signal when the simulator monitor function is triggered.

16. The apparatus of claim 12 wherein the design information receiver comprises a lexical analyzer capable of generating tokens according to an output report received from a circuit design tool.

17. The apparatus of claim 12 wherein the circuit condition identifier comprises a parser capable of identifying one or more of a noise event, a coupling event, a timing event, a race event and a dynamic hazard.

18. The apparatus of claim 12 wherein the circuit condition identifier comprises a parser capable of analyzing the structure of received tokens in accordance with a pre-established electrical event definition.

19. The apparatus of claim 12 wherein the evaluation unit comprises:
description file generator capable of generating a description file that is readable by one or more of an automatic test pattern generator, a fault simulator, and a vector tester; and
test executive module capable of starting one or more of an automatic test pattern generator, a fault simulator, and a vector tester using said generated description file as an input.

20. The apparatus of claim 12 further comprising a design verification director capable of:
directing the received electrical condition to a design verification tool;
starting a design verification tool;
receiving an output from the design verification tool; and
issuing a signal when the identified electrical circuit condition is not detected in the received design verification tool output.

21. A computer-readable medium having computer-executable functions for characterizing an electronic circuit comprising:
receiving design information from a circuit design tool;
identifying an electrical circuit condition that requires test based on the design information;
determining a design verification test;
evaluating the effectiveness of the design verification test in exercising the electrical circuit condition; and
determining a second design verification test and also evaluating the effectiveness of the second design verification test in exercising the electrical circuit condition when the first design verification test does not effectively exercise the electrical circuit condition.

22. The computer-readable medium of claim 21 wherein determining a design verification test comprises:
generating a design verification test using one or more of a manual test definition process, an algorithmic test definition process, a random test definition process and an exhaustive test definition process.

23. The computer-readable medium of claim 21 wherein evaluating the effectiveness of the design verification test comprises:
executing the design verification test in a simulator; and
recognizing the presence of the electrical circuit condition in the simulator results.

24. The computer-readable medium of claim 21 wherein evaluating the effectiveness of the design verification test comprises:
representing the electrical condition in a simulator monitor function, executing the design verification test and the simulator monitor function in a simulator; and
monitoring the activity of the simulator monitor function.

25. The computer-readable medium of claim 21 wherein receiving design information comprises:
parsing an output report from a circuit design tool; and
generating tokens representing the parsed output report.

26. The computer-readable medium of claim 21 wherein identifying an electrical circuit condition comprises one or more of identifying a noise event, identifying a coupling event, identifying a timing event, identifying a race event, and identifying a dynamic hazard.

27. The computer-readable medium of claim 21 wherein identifying an electrical circuit condition comprises:
receiving tokens descriptive of the design information; and
analyze the structure of the tokens in accordance with a pre-established electrical event definition.

28. The computer-readable medium of claim 21 wherein evaluating the effectiveness of the design verification test comprises:
generating a description file readable by one or more of an automatic test pattern generator, a fault simulator, and a vector tester; and
causing one or more of an automatic test pattern generator, a fault simulator, and a vector tester to be executed using said generated description file as an input.

29. The computer-readable medium of claim 21 further comprising:
receiving the electrical circuit condition in a design verification tool; and
verifying the design of the electronic circuit based on the electrical circuit condition.

30. The computer-readable medium of claim 29 wherein verifying the design comprises simulating one or more of a noise event, a coupling event, a timing event, a race event, and a dynamic hazard.

31. The computer-readable medium of claim 29 wherein verifying the design comprises automatically generating a test pattern for testing one or more of a noise event, a coupling event, a timing event, a race event, and a dynamic hazard.

32. An apparatus for characterizing an electronic circuit comprising:
means for receiving circuit design information;
means for identifying electrical circuit conditions that require test;
means for selecting a first design verification test;
means for evaluating the effectiveness of the first design verification test in exercising the identified electrical circuit condition; and
means for selecting a second design verification test when the first design verification test is found to be ineffective.
